(19) United States
(12) Patent Application Publication
(10) Pub. No.: US 2025/0226803 A1
(43) Pub. Date: Jul. 10, 2025

(54) VOLTAGE LEVEL SHIFTER

(71) Applicant: Microchip Technology Incorporated, Chandler, AZ (US)

(72) Inventor: David Gammie, Chandler, AZ (US)

(21) Appl. No.: 19/010,876

(22) Filed: Jan. 6, 2025

Related U.S. Application Data
(60) Provisional application No. 63/617,465, filed on Jan. 4, 2024.

(51) Int. Cl. H03F 3/45; H03K 19/0185

(52) U.S. Cl. CPC H03F 3/45183; H03K 19/018528

(57) ABSTRACT

An apparatus may include a first node coupled to a first terminal, the first terminal to receive a first control signal; a second node coupled to a second terminal, the second terminal to receive a second control signal; a first capacitor having a first plate coupled to the first node and a second plate coupled to a first output terminal; a second capacitor having a first plate coupled to the second node and a second plate coupled to a second output terminal; a first stack of transistors coupled between a positive supply terminal and a common mode terminal, the first stack operable to divide voltage; and a second stack of transistors coupled between a negative supply terminal and the common mode terminal, the second stack operable to divide voltage.

### CROSS-REFERENCE TO RELATED APPLICATION

This application claims the benefit under 35 U.S.C. § 119(e) of U.S. Provisional Patent Application Ser. No. 63/617,465, filed Jan. 4, 2024, the disclosure of which is hereby incorporated herein in its entirety by this reference.

### FIELD

Examples relate to level shifting. Examples relate to current sensing. Current Sensing in SiC-Based Bidirectional Circuit Interruption Device.

### BACKGROUND

A voltage level shifter is an electronic device or circuit that converts voltage levels from a first voltage level to a second, different voltage level. Voltage level shifters are utilized in a variety of operational context, for example, to interface components, circuits, systems, or devices that operate at different voltage domains.

### BRIEF DESCRIPTION OF THE DRAWINGS

To easily identify the discussion of any particular element or act, the most significant digit or digits in a reference number refer to the figure number in which that element is first introduced.

FIG. 1 is a schematic diagram depicting a circuit to level shift a differential signal, in accordance with one or more examples.

FIG. 2 is as a schematic diagram depicting a differential amplification circuit, in accordance with one or more examples.

FIG. 3 is a graph depicting the transient voltage response of an example voltage level shifter over time.

FIG. 4 is a block diagram of circuitry that, in some examples, may be used to implement various functions, operations, acts, processes, or methods disclosed herein.

### DETAILED DESCRIPTION

In the following detailed description, reference is made to the accompanying drawings, which form a part hereof, and in which are shown, by way of illustration, specific examples of embodiments in which the present disclosure may be practiced. These embodiments are described in sufficient detail to enable a person of ordinary skill in the art to practice the present disclosure. However, other embodiments may be utilized, and structural, material, and process changes may be made without departing from the scope of the disclosure.

The illustrations presented herein are not meant to be actual views of any particular method, system, device, or structure, but are merely idealized representations that are employed to describe the embodiments of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed embodiments. The use of the terms “exemplary,” “by example,” and “for example,” means that the related description is explanatory, and though the scope of the disclosure is intended to encompass the examples and legal equivalents, the use of such terms is not intended to limit the scope of an embodiment or this disclosure to the specified components, steps, features, functions, or the like.

It will be readily understood that the components of the embodiments as generally described herein and illustrated in the drawing could be arranged and designed in a wide variety of different configurations. Thus, the following description of various embodiments is not intended to limit the scope of the present disclosure, but is merely representative of various embodiments. While the various aspects of the embodiments may be presented in drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art would understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal.

The various illustrative logical blocks, modules, and circuits described in connection with the embodiments disclosed herein may be implemented or performed with a general purpose processor, a special purpose processor, a Digital Signal Processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer executes computing instructions (e.g., software code) related to embodiments of the present disclosure.

The embodiments may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, a subprogram, without limitation. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may comprise one or more elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

As used herein, any relational term, such as “over,” “under,” “on,” “underlying,” “upper,” “lower,” without limitation, is used for clarity and convenience in understanding the disclosure and accompanying drawings and does not connote or depend on any specific preference, orientation, or order, except where the context clearly indicates otherwise.

In this description the term “coupled” and derivatives thereof may be used to indicate that two elements co-operate or interact with each other. When an element is described as being “coupled” to another element, then the elements may be in direct physical or electrical contact or there may be intervening elements or layers present. In contrast, when an element is described as being “directly coupled” to another element, then there are no intervening elements or layers present. The term “connected” may be used in this description interchangeably with the term “coupled,” and has the same meaning unless expressly indicated otherwise or the context would indicate otherwise to a person having ordinary skill in the art.

As used herein, the terms “assert,” “de-assert” and derivatives thereof used in reference to a pin, means, respectively, to assert or de-assert a signal associated with the pin (e.g., a signal specifically assigned to the pin or a signal to which the pin is specifically assigned, without limitation).

In systems where signals pass between components operating at different voltage levels, such as between a 3.3V low-voltage domain and a 100V high-voltage (HV) domain, propagation may be slowed by level shifters used to shift the signals between the various voltage levels.

The process of shifting these signals may be slowed by the limitations of standard level shifters. For example, standard level shifters rely on transistors or other circuit elements that introduce delays due to their switching times. High-voltage transistors, in particular, are slower because they are designed with thicker oxide layers or larger dimensions to withstand high voltages, increasing capacitance and resistance. Moreover, parasitic capacitances in high-voltage devices can further slow the charging and discharging required for switching.

Standard level shifters may struggle to keep up with fast-changing common-mode voltages (e.g., in differential signals with high common-mode dynamics, without limitation). This can result in incomplete or inaccurate level shifting.

Slow level shifters may fail to support high-speed or high-frequency signals. This is critical in applications such as current sensing or data transmission, where signals may operate in the megahertz (MHz) range or higher. For example, high-voltage level shifters may need to align with clock signals for timing-critical applications (e.g., sampling circuits, without limitation). A slow level shifter introduces misalignment or jitter in clock edges, leading to inaccurate signal interpretation or data corruption.

In many high-voltage systems, signals in one voltage domain must be synchronized with signals in another domain to maintain proper timing (e.g., sampling circuits, without limitation). For example, in differential current sensing applications, the sampling clock should align precisely with the input signal to ensure accurate measurements. However, the slow operation of standard level shifters can cause misalignment of these signals, leading to timing errors or data corruption, especially when dealing with rapidly changing or dynamic signals.

Some applications, such as differential current sensing, involve signals that may swing below ground or have high common-mode voltage variations (the average voltage of the two signals in a differential pair). Standard level shifters often require both NMOS and PMOS gates to handle these conditions, which increases circuit complexity. Furthermore, they may not support below-ground operation without using specialized processes like Silicon-On-Insulator (SOI) technology, which adds cost and complexity. This limitation restricts their use in systems that demand a wide operational range.

In one or more examples, by utilizing capacitors as high-voltage devices (constructed with oxide layers for insulation), a low-voltage differential signal is transferred and immediately, or nearly immediately, interpreted on the high-voltage side of the level translator. These capacitors provide DC high-voltage common-mode isolation, enabling galvanic isolation between voltage domains. The transfer occurs in the AC domain, allowing for ultra-fast level shifting with minimal delay. Additionally, the capacitors serve a further role by functioning as charge pumps, effectively driving the gate of the level shifter. This allows the handling of negative voltages relative to the common-mode level, further broadening the operational range of the circuit.

Transferring signals via capacitors eliminates delays associated with standard, transistor-based level shifting. The AC transfer mechanism ensures low latency and allows rapid synchronization of signals across domain. The capacitors function as charge pumps, allowing the gate of PMOS transistors to handle voltages below the common mode. This allows the circuit to operate effectively with negative and high-voltage signals without requiring additional processing steps. Further, exclusive use of PMOS transistors simplifies the circuit architecture, reducing manufacturing complexity and power consumption vs transistor-based level shifting that uses NMOS transistors. The fast response times and isolation provided by the capacitors allow the level shifter to reject common-mode noise dynamically. The combination of high-speed operation, robustness, and simplified design makes the level shifters in accordance with examples discussed herein suitable for a wider variety of applications compared to standard level shifters, such as in current sensing, high-voltage instrumentation, and circuit protection, without limitation.

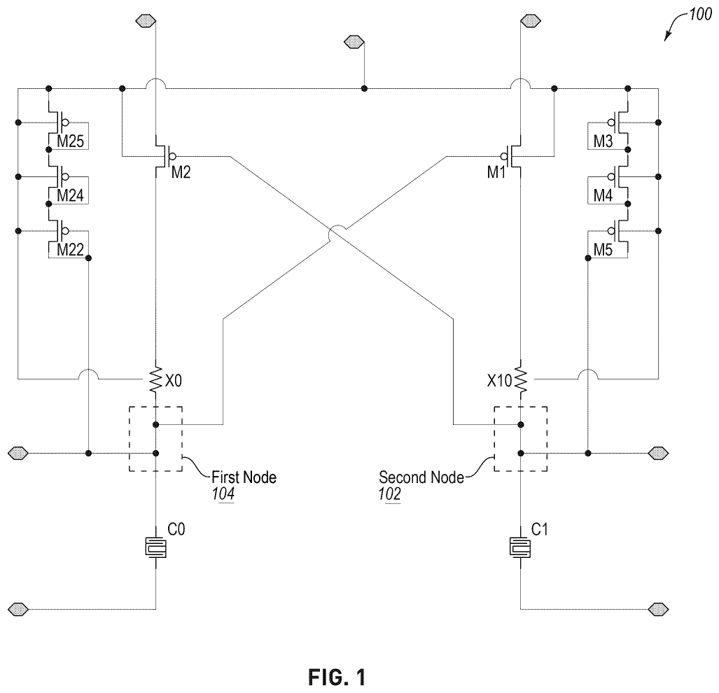

FIG. 1 is a schematic diagram depicting a circuit 100 to level shift a differential signal, in accordance with one or more examples. Circuit 100 may also be referred to as a voltage level shifter 100 or a voltage level shifting circuit 100.

In FIG. 1 control signals S_IN and H_IN are responsible for driving the gates of the PMOS transistors in the level shifter circuit, as discussed below, to control the voltages at terminals S and H, respectively. In operation, their oscillating behavior directly influences the charging and discharging of the gates, enabling the PMOS transistors to switch ON and OFF. The outputs S and H are generated based on the operation of the PMOS transistors, which are driven by S_IN and H_IN.

First node 104 is coupled to a terminal of resistor X0, the input S_IN, one terminal of capacitor C0, and the gate of PMOS transistor M1. Input S_IN is coupled to the gate of PMOS transistor M22 and switchably coupled to the gates of PMOS transistors M24 and M25. Further terminals of resistor X0 are coupled to common mode terminal CM and to a drain of PMOS transistor M2, respectively. The source of PMOS transistor M2 is coupled to positive supply terminal POS. The other terminal of capacitor C0 is coupled to terminal H.

PMOS transistors M22, M24 and M25 are coupled in series (source to drain) in a stack. The source of PMOS transistor M 25 is coupled to common mode terminal CM. The respective bulk terminals of PMOS transistors M22, M24 and M25 are coupled to common mode terminal CM.

Second node 102 is coupled to a terminal of resistor X10, the input H_IN, one terminal of capacitor C1, and the gate of PMOS transistor M2. Input H_IN is coupled to the gate of PMOS transistor M5 and switchably coupled to the gates of PMOS transistors M4 and M3. Further terminals of resistor X10 are coupled to common mode terminal CM and a drain of PMOS transistor M1, respectively. The source of PMOS transistor M1 is coupled to negative supply terminal NEG. The other terminal of capacitor C1 is coupled to terminal S.

PMOS transistors M5, M4 and M3 are coupled in series (source to drain) in a stack. The source of PMOS transistor M3 is coupled to common mode terminal CM. The respective bulk terminals of PMOS transistors M3, M4, and M5 are coupled to common mode terminal CM.

When the stacked transistors M3, M4, and M5 (on the right side) and M22, M24, and M25 (on the left side) are OFF they act as voltage dividers. When the stacked transistors M3, M4, and M5 and stacked transistors M22, M24, and M25 are ON they act as switches, creating a low resistance path and intermediate nodes are pulled to the connected terminal POS or NEG.

Capacitors C0 and C1 serve as coupling elements in the circuit, providing AC coupling and ensuring proper voltage transfer between nodes. Capacitors C0 and C1 allow the differential signal to pass from the respective nodes (controlled by the transistors and input signals S_IN and H_IN) to the output terminals while blocking any DC signals. In this manner, capacitors C0 and C1 isolate first node 104 and second node 102 from terminals H and S, respectively.

In order to handle the high voltages, capacitors C0 and C1 are high-voltage devices constructed with oxide layers for insulation. Nevertheless, they transfer a low-voltage differential signal that is immediately, or nearly immediately, interpreted on the high-voltage side of the level translator.

In one or more examples, capacitors C0 and C1 may temporarily store and transfer charge, effectively boosting control signals S_IN and H_IN at specific times to assist with driving the gates of PMOS transistors M1 and M2, the gates of the stacked transistors, or both. Capacitors C0 and C1 may charge and discharge in a controlled manner, as a non-limiting example, in response to charging signals (not depicted by FIG. 1).

Capacitors C0 and C1 acting as coupling capacitors enable rapid transfer of the differential signal across nodes without relying on slow resistive pathways. Capacitive coupling avoids the delays associated with resistive-capacitive (RC) time constants in purely resistive networks.

In one or more examples, the PMOS transistors may have optimized gate areas, minimizing their parasitic capacitances. Smaller gate capacitances reduce the load on the control nodes, allowing input signals (S_IN and H_IN) to transition the gate voltages quickly. Reduced capacitive loading at the gates also ensures rapid switching of the PMOS transistors.

The capacitors C0 and C1 function as charge pumps, dynamically boosting the voltage at the control nodes during transitions. This assists the control signals (S_IN and H_IN) by rapidly charging or discharging the gates of the PMOS transistors, ensuring fast and reliable switching.

Capacitors C0 and C1 provide galvanic isolation, decoupling the high-voltage domain from the low-voltage outputs. This isolation reduces cross-talk and interference, allowing the circuit to operate reliably at higher speeds.

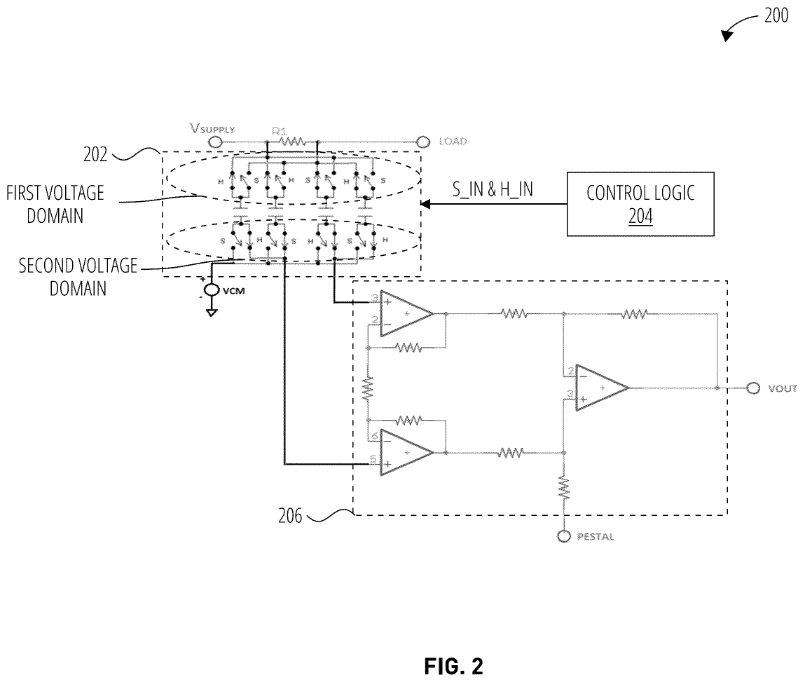

FIG. 2 is a schematic diagram depicting a differential amplification circuit 200, in accordance with one or more examples.

The circuit 200 includes control logic 204, differential amplifier 206, and operative coupling 202 to couple input signal source (here, Vsupply and Load) to inputs of differential amplifier 206. Operative coupling 202 uses pairs of capacitors that alternately perform integration and transfer of a differential voltage signal while maintaining fidelity with a controlled common mode voltage. During the integration phase, the capacitors store a combination of the differential signal and the common mode voltage, and during the transfer phase, they deliver the stored signal to the input of a differential amplification circuit. This alternating operation, driven by control signals, isolates DC common mode voltage while enabling high-frequency AC signal transfer. The capacitors effectively provide DC isolation and AC coupling, ensuring precise signal transmission with high fidelity.

The top switches and bottom switches are in two different voltage domains and need to be synchronized and operating at e.g., 100 MHz, without limitation. Only one type of transmission gate is used for the switches, a PMOS transistor. The switches need to reach (charge to) the ON voltage and/or OFF voltage. Accordingly, in one or more examples, the ultra-fast isolating, charge pumping level shifter of FIG. 1 (voltage level shifter 100) is used. Voltage level shifter 100 receives S_IN and H_IN, generated by control logic 204.

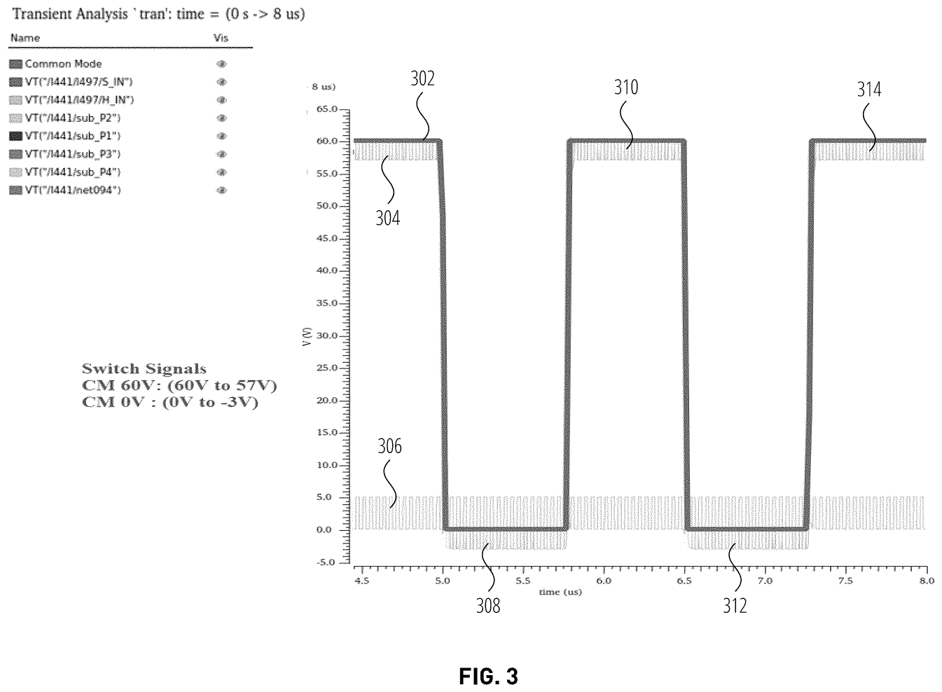

FIG. 3 is a graph depicting the transient voltage response of a voltage level shifter circuit over time. Signals are plotted to illustrate how the circuit operates under different conditions. Depicted elements include common mode signals, switching behavior, and voltage levels corresponding to different states of the circuit.

Line 302 shows a high-voltage signal alternating between two states: CM=60V, where the voltage swings between 60V and 57V; and CM=0V, where the voltage swings between 0V and −3V.

Oscillating part 304, oscillating part 308, oscillating part 310, oscillating part 312, and oscillating part 314 represent S_IN and H_IN, the input control signals. Both signals are small in amplitude, high-frequency, and oscillate rapidly, appearing to blend together in FIG. 3 due to their frequency and alignment.

Oscillating part 306 represents the outputs at terminals H and S. The outputs are complementary and exhibit larger amplitude swings, transitioning between defined voltage levels (e.g., 0V to 5V).

When S_IN or H_IN is negative relative to CM, the gate of the PMOS transistor is negatively charged with respect to CM, ensuring conduction. When S_IN or H_IN is positive relative to CM, the gate is positively charged with respect to CM, turning the transistor OFF.

In a current sense topology, sampling can be as high as 200 MHz and the clocks need to be extremely fast to coordinate the edges with the sampling at the possibly high voltage common mode input and synchronize with the low voltage of switches. A current sense (e.g., a current sense circuit or device, without limitation) that implements a level shifter discussed herein may have high voltage common mode or common mode below ground (ground voltage) and high-voltage capacitors discussed herein provide isolation. By transferring a discrete voltage package the voltage at the common mode shifts and allows for negative voltage with respect to the common mode (which can be negative with respect to ground if the common mode is ground), this feature gives the added benefit of allowing only one use of transmission gate (PMOS) which in turn can be used as a switch with isolation from N material being placed negative (body).

One or more examples are dynamic and fast, and may be used, as a non-limiting example, to sample at a fast rate which allows a high common mode AC rejection. In a unique current sensing architecture (input capacitors used for isolation and thus subject to common mode perturbations), the ultra-fast sampling rate reduces these perturbations.

One or more examples simplify differential measurements allowing the signal to pass through switches (which are isolated) and then high voltage capacitors, allowing galvanic isolation from the input signal.

Non-limiting examples of applications include: solid-state circuit breaker (SSCB), electronic fuse (E-Fuse), solid-state relay (SSR), high voltage differential amplifier, high voltage sensing, ground sensing, and DCR sensing.

One or more examples relate to High Voltage Level Shifter which can be used for Isolation without HV devices and Charge pumping effect to use only PMOS transmission gates when passing low common or high common mode signal voltages.

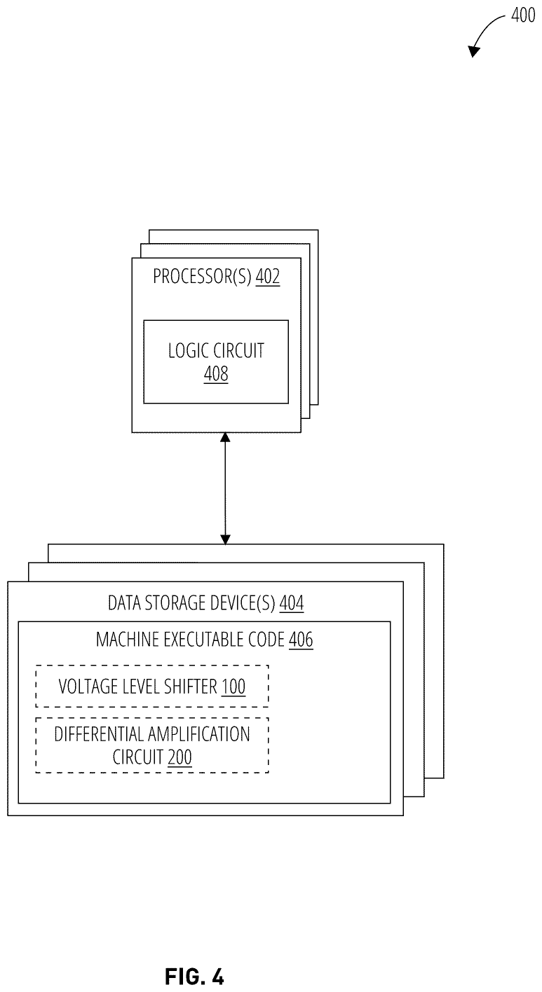

It will be appreciated by those of ordinary skill in the art that functional elements of examples disclosed herein (e.g., functions, operations, acts, processes, or methods) may be implemented in any suitable hardware, software, firmware, or combinations thereof. FIG. 4 illustrates non-limiting examples of implementations of functional elements disclosed herein. In some examples, some or all portions of the functional elements disclosed herein may be performed by hardware capable of carrying out the functional elements.

FIG. 4 is a block diagram of a circuitry 400 that, in some examples, may be used to implement various functions, operations, acts, processes, or methods disclosed herein. The circuitry 400 includes one or more processors 402 (sometimes referred to herein as “processors 402”) operably coupled to one or more data storage devices 404 (sometimes referred to herein as “storage 404”). The storage 404 includes machine executable code 406 stored thereon and the processors 402 include logic circuit 408. The machine executable code 406 includes information describing functional elements that may be implemented by (e.g., performed by) the logic circuit 408. The logic circuit 408 is adapted to implement (e.g., perform) the functional elements described by the machine executable code 406. The circuitry 400, when executing the functional elements described by the machine executable code 406, should be considered as special purpose hardware for carrying out functional elements disclosed herein. In one or more examples, the processors 402 may perform the functional elements described by the machine executable code 406 sequentially, concurrently (e.g., on one or more different hardware platforms), or in one or more parallel process streams.

When implemented by logic circuit 408 of the processors 402, the machine executable code 406 adapts the processors 402 to perform operations of examples disclosed herein. By way of non-limiting example, the machine executable code 406 may adapt the processors 402 to perform some or a totality of operations of level shifting or current sensing discussed herein.

Also by way of non-limiting example, the machine executable code 406 may adapt the processors 402 to perform some or a totality of features, functions, or operations disclosed herein for one or more of level shifting and current sensing discussed herein, including of circuit 100 of FIG. 1 or circuit 200 of FIG. 2.

The processors 402 may include a general purpose processor, a special purpose processor, a central processing unit (CPU), a microcontroller, a programmable logic controller (PLC), a digital signal processor (DSP), an application specific integrated circuit (ASIC), a field-programmable gate array (FPGA) or other programmable logic device (PLD), discrete gate or transistor logic, discrete hardware components, other programmable device, or any combination thereof designed to perform the functions disclosed herein. A general-purpose computer including one or more processors 402, including a general-purpose processor, is considered a special-purpose computer at least while the general-purpose computer executes functional elements corresponding to the machine executable code 406 (e.g., software code, firmware code, configuration data, hardware descriptions, without limitation) related to examples of the present disclosure. It is noted that a general-purpose processor (which may also be referred to herein as a host processor or simply a host) may be a microprocessor, but in the alternative, a general-purpose processor of processors 402 may include any conventional processor, controller, microcontroller, or state-machine. An FPGA or other PLD of the processors 402 may be configured (e.g., programmed, without limitation) with configuration data to perform functions disclosed herein, or, additionally or alternatively, may be capable of being configured or re-configured (e.g., programmable, or re-programmable, without limitation) with configuration data to perform functions disclosed herein. The processors 402 may also be implemented as a combination of computing devices, such as a combination of a DSP and a microprocessor, a plurality of microprocessors, one or more microprocessors in conjunction with a DSP core, or any other such configuration.

In one or more examples, the storage 404 includes volatile data storage (e.g., random-access memory (RAM), static RAM (SRAM), without limitation) and non-volatile data storage (e.g., Flash memory, a hard disc drive, a solid state drive, erasable programmable read-only memory (EPROM), without limitation). In some examples, the processors 402 and the storage 404 may be implemented into a single device (e.g., a semiconductor device product, a system on chip (SOC), without limitation). In some examples, the processors 402 and the storage 404 may be implemented into separate devices.

In one or more examples the machine executable code 406 may include computer-readable instructions (e.g., software code, firmware code). By way of non-limiting example, the computer-readable instructions may be stored by the storage 404, accessed directly by the processors 402, and executed by the processors 402 using at least the logic circuit 408. Also by way of non-limiting example, the computer-readable instructions may be stored on the storage 404, transferred to a memory device (not shown) for execution, and executed by the processors 402 using at least the logic circuit 408. Processors 402 or logic circuit 408 thereof be coupled to such a memory device or include such a memory device (e.g., a configuration memory cell, without limitation). Accordingly, in some examples, the logic circuit 408 includes electrically configurable logic circuit 408.

In one or more examples, the machine executable code 406 may describe hardware (e.g., circuitry) to be implemented in the logic circuit 408 to perform the functional elements. This hardware may be described at any of a variety of levels of abstraction, from low-level transistor layouts to high-level description languages. At a high-level of abstraction, a hardware description language (HDL) such as an IEEE Standard hardware description language (HDL) may be used. By way of non-limiting examples, VERILOG®, SYSTEMVERILOG™, or very-large scale integration (VLSI) hardware description language (VHDL) may be used.

HDL descriptions may be converted into descriptions at any of numerous other levels of abstraction as desired. As a non-limiting example, a high-level description can be converted to a logic-level description such as a register-transfer language (RTL), a gate-level (GL) description, a layout-level description, or a mask-level description. As a non-limiting example, micro-operations to be performed by hardware logic circuits (e.g., gates, flip-flops, registers, without limitation) of the logic circuit 408 may be described in an RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in some examples, the machine executable code 406 may include an HDL, an RTL, a GL description, a mask level description, other hardware description, or any combination thereof.

In examples where the machine executable code 406 includes a hardware description (at any level of abstraction), a system (not shown, but including the storage 404) implements the hardware description described by the machine executable code 406. By way of non-limiting example, the processors 402 may include a programmable logic device (e.g., an FPGA or a PLC, without limitation) and the logic circuit 408 may be electrically controlled (e.g., via configuration data, without limitation) to implement circuitry corresponding to the hardware description into the logic circuit 408. Also by way of non-limiting example, the logic circuit 408 may include hard-wired logic manufactured by a manufacturing system (not shown, but including the storage 404) according to the hardware description of the machine executable code 406.

Regardless of whether the machine executable code 406 includes computer-readable instructions or a hardware description, the logic circuit 408 is adapted to perform the functional elements described by the machine executable code 406 when implementing the functional elements of the machine executable code 406. It is noted that although a hardware description may not directly describe functional elements, a hardware description indirectly describes functional elements that the hardware elements described by the hardware description are capable of performing.

As used in the present disclosure, the terms “module” or “component” may refer to specific hardware implementations to perform the actions of the module or component and/or software objects or software routines that may be stored on and/or executed by general purpose hardware (e.g., computer-readable media, processing devices, without limitation) of the computing system. In some examples, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations or a combination of software and specific hardware implementations are also possible and contemplated.

As used in the present disclosure, the term “combination” with reference to a plurality of elements may include a combination of all the elements or any of various different subcombinations of some of the elements. For example, the phrase “A, B, C, D, or combinations thereof” may refer to any one of A, B, C, or D; the combination of each of A, B, C, and D; and any subcombination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims, without limitation) are generally intended as “open” terms (e.g., the term “including” should be interpreted as “including, but not limited to,” the term “having” should be interpreted as “having at least,” the term “includes” should be interpreted as “includes, but is not limited to,” without limitation). As used herein, the term “each” means “some or a totality.” As used herein, the term “each and every” means a “totality.”

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more,” without limitation); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations, without limitation). Furthermore, in those instances where a convention analogous to “at least one of A, B, and C, without limitation” or “one or more of A, B, and C, without limitation” is used, in general such a construction is intended to include A alone, B alone, C alone, A and B together, A and C together, B and C together, or A, B, and C together, without limitation.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additional non-limiting examples include:
Example 1: An apparatus, comprising: a first node coupled to a first terminal, the first terminal to receive a first control signal; a second node coupled to a second terminal, the second terminal to receive a second control signal; a first capacitor having a first plate coupled to the first node and a second plate coupled to a first output terminal; a second capacitor having a first plate coupled to the second node and a second plate coupled to a second output terminal; a first stack of transistors coupled between a positive supply terminal and a common mode terminal, the first stack operable to divide voltage; a second stack of transistors coupled between a negative supply terminal and the common mode terminal, the second stack operable to divide voltage.
Example 2: The apparatus according to Example 1, wherein the first node coupled to a resistor, the resistor coupled to the common mode terminal and to a gate of a first transistor in the first stack.
Example 3: The apparatus according to Examples 1 and 2, wherein the second node coupled to a resistor, the resistor coupled to the common mode terminal and to a gate of a first transistor in the second stack.
Example 4: The apparatus according to any of Examples 1 to 3, wherein the first and second capacitors to transfer differential signals between the first and second nodes and the output terminals and block DC components.
Example 5: The apparatus according to any of Examples 1 to 4, wherein the first and second capacitors are high-voltage capacitors with oxide insulation layers to provide galvanic isolation between the first and second nodes and the output terminals.
Example 6: The apparatus according to any of Examples 1 to 5, wherein the transistors in the first and second stacks are PMOS transistors coupled source-to-drain in series.
Example 7: The apparatus according to any of Examples 1 to 6, wherein each transistor in the first and second stacks has a bulk terminal coupled to the common mode terminal.
Example 8: The apparatus according to any of Examples 1 to 7, wherein the first and second capacitors to dynamically store and transfer charge to boost control signals received at the first and second terminals.
Example 9: The apparatus according to any of Examples 1 to 8, wherein the first node coupled to a gate of a first PMOS transistor, and the second node coupled to a gate of a second PMOS transistor, the first and second PMOS transistors to control current flow through the first and second stacks, respectively.
Example 10: The apparatus according to any of Examples 1 to 9, comprising: a first resistor coupled between the first node and the common mode terminal; a second resistor coupled between the second node and the common mode terminal.
Example 11: An apparatus, comprising: a differential amplifier; and a circuit to provide an input signal to inputs of the differential amplifier, the circuit comprising: a first voltage domain comprising first switches; a second voltage domain comprising second switches; and capacitors to provide AC coupling between the first voltage domain and the second voltage domain, and wherein the switches in the first voltage domain and the switches in the second voltage domain exhibit matched transmission gate characteristics.
Example 12: The apparatus according to Example 11, wherein the switches in the first voltage domain and the switches in the second voltage domain exhibit substantially similar switching behavior. or provide substantially equivalent switching functionality.
Example 13: The apparatus according to Examples 11 and 12, wherein the switches in the first voltage domain and the switches in the second voltage domain comprise PMOS transistors.
Example 14: The apparatus according to any of Examples 11 to 13, comprising a controller to produce control signals, wherein the switches are configured to operate in response to the control signals.
Example 15: The apparatus according to any of Examples 11 to 14, wherein the controller, via the control signals, to cause the capacitors to alternately couple the first voltage domain and the second voltage domain.
Example 16: The apparatus according to any of Examples 11 to 15, wherein the controller to generate the control signals synchronized to alternately drive the switches in the first voltage domain and the switches in the second voltage domain.
Example 17: The apparatus according to any of Examples 11 to 16, wherein the capacitors to alternately integrate and transfer portions of the input signal between the first voltage domain and the second voltage domain.
Example 18: The apparatus according to any of Examples 11 to 17, wherein the capacitors to provide galvanic isolation between the first voltage domain and the second voltage domain while coupling the input signal.
Example 19: The apparatus according to any of Examples 11 to 18, wherein the capacitors are high-voltage capacitors configured to handle input signals with high common mode voltage variations.
Example 20: The apparatus according to any of Examples 11 to 19, wherein the differential amplifier is configured to amplify the input signal while rejecting common mode noise.
Example 21: The apparatus according to any of Examples 11 to 20, wherein the switches are configured to provide a low-resistance path when ON and a high-resistance path when OFF, enabling integration and transfer phases of the capacitors.
Example 22: The apparatus according to any of Examples 11 to 21, wherein the capacitors are configured to block DC components of the input signal while transferring AC components to the differential amplifier.

While the present disclosure has been described herein with respect to certain illustrated examples, those of ordinary skill in the art will recognize and appreciate that the present invention is not so limited. Rather, many additions, deletions, and modifications to the illustrated and described examples may be made without departing from the scope of the invention as hereinafter claimed along with their legal equivalents. In addition, features from one example may be combined with features of another example while still being encompassed within the scope of the invention as contemplated by the inventor.

What is claimed is:

1. An apparatus, comprising:
a first node coupled to a first terminal, the first terminal to receive a first control signal;
a second node coupled to a second terminal, the second terminal to receive a second control signal;
a first capacitor having a first plate coupled to the first node and a second plate coupled to a first output terminal;
a second capacitor having a first plate coupled to the second node and a second plate coupled to a second output terminal;
a first stack of transistors coupled between a positive supply terminal and a common mode terminal, the first stack operable to divide voltage; and
a second stack of transistors coupled between a negative supply terminal and the common mode terminal, the second stack operable to divide voltage.

2. The apparatus of claim 1, wherein the first node coupled to a resistor, the resistor coupled to the common mode terminal and to a gate of a first transistor in the first stack.

3. The apparatus of claim 1, wherein the second node coupled to a resistor, the resistor coupled to the common mode terminal and to a gate of a first transistor in the second stack.

4. The apparatus of claim 1, wherein the first and second capacitors to transfer differential signals between the first and second nodes and the output terminals and block DC components.

5. The apparatus of claim 1, wherein the first and second capacitors are high-voltage capacitors with oxide insulation layers to provide galvanic isolation between the first and second nodes and the output terminals.

6. The apparatus of claim 1, wherein the transistors in the first and second stacks are PMOS transistors coupled source-to-drain in series.

7. The apparatus of claim 6, wherein each transistor in the first and second stacks has a bulk terminal coupled to the common mode terminal.

8. The apparatus of claim 1, wherein the first and second capacitors to dynamically store and transfer charge to boost control signals received at the first and second terminals.

9. The apparatus of claim 1, wherein the first node coupled to a gate of a first PMOS transistor, and the second node coupled to a gate of a second PMOS transistor, the first and second PMOS transistors to control current flow through the first and second stacks, respectively.

10. The apparatus of claim 1, comprising:
a first resistor coupled between the first node and the common mode terminal;
a second resistor coupled between the second node and the common mode terminal.

11. An apparatus, comprising:
a differential amplifier; and
a circuit to provide an input signal to inputs of the differential amplifier, the circuit comprising:
a first voltage domain comprising first switches;
a second voltage domain comprising second switches; and
capacitors to provide AC coupling between the first voltage domain and the second voltage domain,
wherein the switches in the first voltage domain and the switches in the second voltage domain exhibit matched transmission gate characteristics.

12. The apparatus of claim 11, wherein the switches in the first voltage domain and the switches in the second voltage domain exhibit substantially similar switching behavior. or provide substantially equivalent switching functionality.

13. The apparatus of claim 11, wherein the switches in the first voltage domain and the switches in the second voltage domain comprise PMOS transistors.

14. The apparatus of claim 11, comprising a controller to produce control signals, wherein the switches are configured to operate in response to the control signals.

15. The apparatus of claim 14, wherein the controller, via the control signals, to cause the capacitors to alternately couple the first voltage domain and the second voltage domain.

16. The apparatus of claim 14, wherein the controller to generate the control signals synchronized to alternately drive the switches in the first voltage domain and the switches in the second voltage domain.

17. The apparatus of claim 11, wherein the capacitors to alternately integrate and transfer portions of the input signal between the first voltage domain and the second voltage domain.

18. The apparatus of claim 11, wherein the capacitors to provide galvanic isolation between the first voltage domain and the second voltage domain while coupling the input signal.

19. The apparatus of claim 11, wherein the capacitors are high-voltage capacitors configured to handle input signals with high common mode voltage variations.

20. The apparatus of claim 11, wherein the differential amplifier is configured to amplify the input signal while rejecting common mode noise.

21. The apparatus of claim 11, wherein the switches are configured to provide a low-resistance path when ON and a high-resistance path when OFF, enabling integration and transfer phases of the capacitors.

22. The apparatus of claim 11, wherein the capacitors are configured to block DC components of the input signal while transferring AC components to the differential amplifier.
